(19) United States
(12) Patent Application Publication
(10) Pub. No.: US 2016/0313834 A1
(43) Pub. Date: Oct. 27, 2016

(54) DISPLAY DEVICE

(71) Applicant: EVERDISPLAY OPTRONICS (SHANGHAI) LIMITED, Shanghai City (CN)

(72) Inventors: Kunliang MA, SHANGHAI CITY (CN); Chih-wei WEN, SHANGHAI CITY (CN)

(73) Assignee: EVERDISPLAY OPTRONICS (SHANGHAI) LIMITED, SHANGHAI CITY (CN)

(21) Appl. No.: 15/135,045

(22) Filed: Apr. 21, 2016

(30) Foreign Application Priority Data
Apr. 27, 2015 (CN) 201510206805.6

(51) Int. Cl. G06F 3/047; H01L 27/32; H01L 51/52; G06F 3/041

(52) U.S. Cl. CPC G06F 3/047; G06F 3/0412; H01L 27/323; H01L 51/5246; G06F 2203/04102; G06F 2203/04103; H01L 2251/5338

(57) ABSTRACT

The present disclosure provides a display device having a display region and a periphery region. The display device includes a display panel, a first flexible circuit board for performing display and a second flexible circuit board for touch. The display panel includes: a first substrate; a display element; a touch panel; and a second substrate. The second substrate is provided with a first gap in the periphery region, and the first gap exposes the display wire, and the first substrate is provided with two second gaps in the periphery region, and the two second gaps are respectively located at both sides of the first gap and expose the touch wires.

### CROSS REFERENCE

This application is based upon and claims priority to Chinese Patent Application No. 201510206805.6, filed Apr. 27, 2015, the entire contents of which are incorporated herein by reference.

### TECHNICAL FIELD

The present disclosure generally relates to the field of display technology, and more particularly, to a display device.

### BACKGROUND

In recent years, OLED (Organic Light-Emitting Diode) technology has been rapidly developed, and has become a promising technology that most likely replaces an LED (Liquid Crystal Display). Moreover, in recent years, demands for display devices having touch-sensing functions are also gradually increasing. According to the manner for incorporating a touch panel into a display panel, the display devices may be roughly divided into for example out-cell display devices and in-cell display devices. A user may touch a display screen (or a touch-sensing region) of the display device via a stylus, a finger or other objects so as to perform various kinds of functions on the display device.

The display device includes a display region for displaying and a periphery region surrounding the display region. Generally speaking, a flexible circuit board for performing display and a flexible circuit board for touch are electrically bonded to a bonding region in the periphery region of the display device. Since the periphery region has a limited area, the bonding region for bonding the flexible circuit board and the flexible circuit board may be too small to realize bonding.

### SUMMARY

In order to overcome the above-described defects existing in conventional technologies, the present disclosure provides a display device having a periphery region in which a bonding region is reasonably arranged.

The present disclosure provides a display device having a display region and a periphery region, wherein the display device includes: a display panel which includes: a first substrate; a display element located in the display region on the first substrate and having a display wire extending to the periphery region; a touch panel located in the display region on the display element and having touch wires extending to the periphery region; and a second substrate located on the touch panel and being opposite to the first substrate, wherein the second substrate is provided with a first gap in the periphery region, and the first gap exposes the display wire, and the first substrate is provided with two second gaps in the periphery region, the two second gaps are respectively located at both sides of the first gap and expose the touch wires; a first flexible circuit board for performing display and electrically connected to the display wire exposed by the first gap; and a second flexible circuit board for touch and electrically connected to the touch wires exposed by the two second gaps.

Preferably, the first gap is located in a middle region of one side of the periphery region.

Preferably, the two second gaps are located at both sides of the first recess and extend to edges of the display panel.

Preferably, the first gap and the second gaps have any one shape selected from a group composed of a triangle, a rectangle, a trapezoid, a hexagon and an octagon.

Preferably, the first gap and the second gaps are located along a short side of the periphery region.

Preferably, the display device further includes a first thin film layer located between the touch panel and the second substrate, wherein the first gap is formed through the second substrate and the first thin film layer.

Preferably, the first thin film layer is a sealing layer.

Preferably, the display device further includes a second thin film layer located between the first substrate and the touch panel, wherein the second gaps are formed through the first substrate and the second thin film layer.

Preferably, the second thin film layer is a low temperature polysilicon layer.

Preferably, the second flexible circuit board has two golden fingers electrically connected to the touch wires exposed by the second gaps, respectively.

Preferably, the second flexible circuit board is approximately Y-shaped.

Preferably, the display element is an organic light emitting display element.

Preferably, the periphery region surrounds the display region.

As compared to the conventional technologies, by appropriately arranging a bonding region for bonding the first flexible circuit board and the second flexible circuit board in a periphery region of a display device, the present disclosure has the following advantages:

1) circuit designs and wiring principles of the display panel and the flexible circuit boards of the present disclosure do not need to change, and the present disclosure is an improvement based on conventional processes;

2) without reduction of the bonding region of the in-cell first flexible circuit board, the present disclosure may increase the area of the bonding region(s) of the second flexible circuit board by boding the second flexible circuit board at both sides; and

3) the display device of the present disclosure has more advantages in an in-cell structure of a small-sized cellphone or tablet PC.

### BRIEF DESCRIPTION OF THE DRAWINGS

Exemplary embodiments thereof are described in detail with reference to the accompanying drawings, the above and other features and advantages of the present disclosure will become more apparent.

FIG. 1 is a structure diagram illustrating a display device in conventional technologies.

FIG. 2 is a structure diagram illustrating a display device according to an embodiment of the present disclosure.

FIG. 3 is a cross-sectional view of a display device taken along an A-A′ direction in FIG. 2 according to an embodiment of the present disclosure.

FIG. 4 is a cross-sectional view of a display device taken along a B-B′ direction in FIG. 2 according to an embodiment of the present disclosure.

FIG. 5 is a diagram illustrating a bonding region of a display device according to an embodiment of the present disclosure.

Reference numerals are defined as follows:
100 display device
110 periphery region
120 display region
131 first gap
132 second gap
150 flexible circuit board for touch
200 display device
201 first substrate
202 second thin film layer
203 display element
204 touch panel
205 first thin film layer
206 second substrate
207 display wire
208 touch wires
210 periphery region
220 display region
231 first gap
232 second gap
240 bonding region
250 second flexible circuit board for touch
251, 252 golden fingers

### DETAILED DESCRIPTION

Now exemplary embodiments will be described more fully with reference to the accompanying drawings. However, the exemplary embodiments may be embodied in various forms, and should not be construed as limited to the embodiments set forth herein. Rather, these embodiments are provided so that this disclosure will be thorough and complete, and fully convey the concept of the exemplary embodiments to those skilled in the art. In the drawings, the same reference numerals denote the same or similar structure, and therefore a repetitive description thereof will be omitted.

The described features, structures or characteristics may be combined in any suitable manner in one or more embodiments. In the following description, numerous specific details are provided in order that the embodiments of the present disclosure could be fully understood. However, those skilled in the art will recognize that the technical solution of the present disclosure may be practiced without one or more of the specific details, or may take other methods, components, materials and the like. In some cases, known structures, materials or operations are not shown or described in detail to avoid obscuring aspects of the present disclosure.

The accompanying drawings of the present disclosure are only descriptive of relative position relationships, and in order to facilitate understanding, layer thicknesses of certain parts are drawn in an exaggerated manner and the layer thicknesses in the accompanying drawings do not represent proportional relationships of actual layer thicknesses. Relationships among respective layers herein include direct and indirect contact relationships.

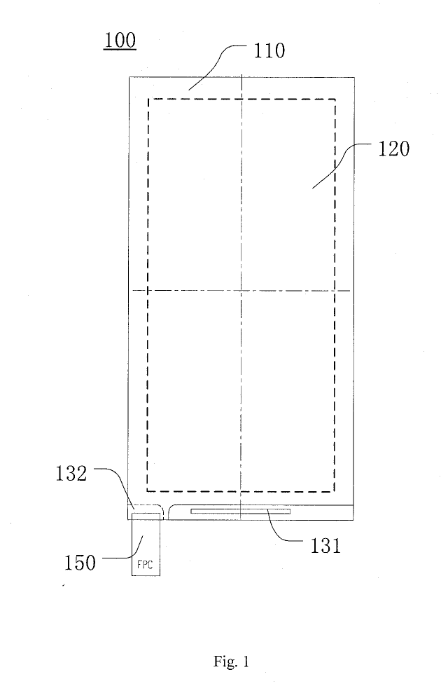

FIG. 1 is a structure diagram illustrating a display device in related arts. A display device 100 has a display region 120 and a periphery region 110 surrounding the display region 120. The display device 100 includes a display panel having a display element and a touch panel. The display element and the touch panel are located in the display region 110. The display element has a display wire extending to the periphery region 110. The touch panel has a touch wire extended to the periphery region 110.

A first gap 131 and a second gap 132 are provided in the periphery region 110 of the display device 100. The first gap 131 exposes the display wire of the display element to bond a flexible circuit board for performing display. The second gap 132 exposes the touch wire of the touch panel to bond a flexible circuit board 150 for touch. The first gap 131 is located in the middle along a short side of the periphery region 110, and one side of the first gap 131 extends to an end of the short side. The second gap 132 is located at the other side of the first gap 131, and extends to the other end of the short side.

Referring to FIG. 1, the second gap 132 for bonding the flexible circuit board 150 for touch is very small. When the size of the display device is reduced, the second gap 132 might become too small, and it will be difficult to bond the flexible circuit board 150 for touch, and this causes a technical bottle.

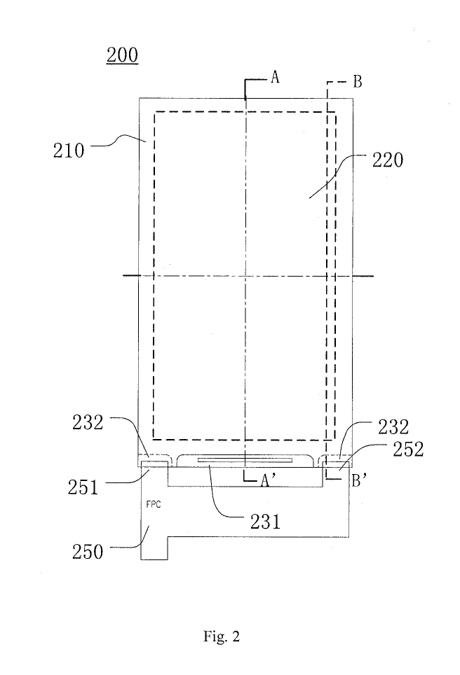

The present disclosure solves the above-described problem by appropriately arranging a bonding region for bonding a flexible circuit board for performing display and a flexible circuit board for touch in a periphery region of a display device. FIG. 2 is a structure diagram illustrating a display device according to an embodiment of the present disclosure. A display device 200 has a display region 220 and a periphery region 210 surrounding the display region 220. The display device 200 includes a display panel having a display element and a touch panel. The display element and the touch panel are located in the display region 220. The display element has a display wire extending to the periphery region 210. The touch panel has touch wires extending to the periphery region 210.

In the periphery region 210 of the display device 200, a first gap 231 and two second gaps 132 located at both sides of the first gap 231 are provided. The first gap 231 exposes the display wire of the display element to bond a first flexible circuit board for performing display. The second gaps 132 expose the touch wires of the touch panel to bond a second flexible circuit board 250 for touch. The first gap 231 is located in the middle region along a short side of the periphery region 210. The two second gaps 232 are located at both sides of the first gap 231, and extending to ends of the short side. The second flexible circuit board 250 for touch has two golden fingers 251 and 252 electrically connected to the touch wires exposed by the two second gaps 232, respectively. The touch wires contain two sets of wires (Tx and Rx) that are perpendicular to each other, the two golden fingers 251 and 252 of the second flexible circuit board 250 for touch may be connected to the two sets of wires (Tx and Rx), respectively, or may be electrically connected to the two sets of wires (Tx and Rx) simultaneously. The second flexible circuit board 250 for touch is approximately Y-shaped. Although the first flexible circuit board and the second flexible circuit board 250 are shown as bonded at the edge of the display panel, they are actually located inside a mobile phone shell.

The first gap and the second gaps may have a triangle shape, a rectangle shape, a trapezoid shape, a hexagon shape or an octagon shape.

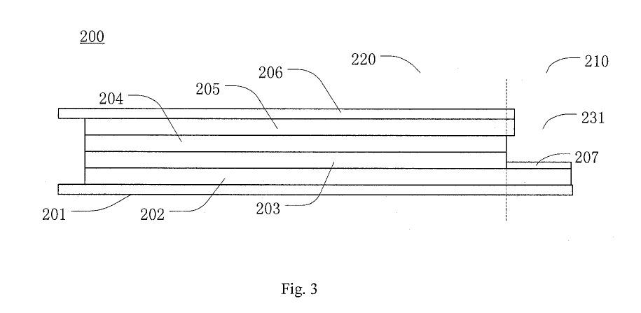

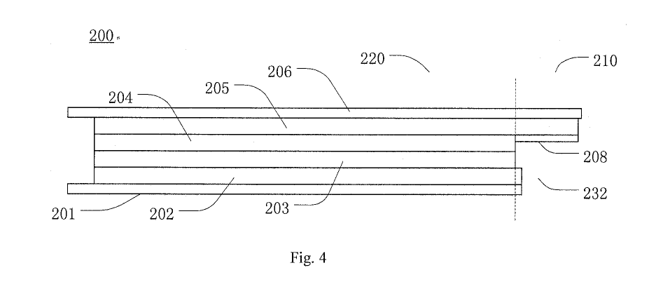

An internal structure of a display device according to an embodiment of the present disclosure is shown in FIGS. 3 and 4.

FIG. 3 is a cross-sectional view of a display device taken along an A-A′ direction in FIG. 2 according to an embodiment of the present disclosure. A display device 200 has a display region 220 and a periphery region 210 surrounding the display region 220. The display device 200 includes a display panel, a first flexible circuit board for performing display (not shown) and a second flexible circuit board 250 for touch. The display panel includes a first substrate 201, a second thin film layer 202, a display element 203, a touch panel 204, a first thin film layer 205 and a second substrate 206. The second thin film layer 202 is formed in the display region 220 on the first substrate 201 and extends to the periphery region 210. The display element 203 is formed in the display region 220 on the second thin film layer 202 and has a display wire 207 extending to the periphery region 210. The touch panel 204 is formed in the display region 220 on the display element 203 and has touch wires 208 extending to the periphery region 210 (as shown in FIG. 4). The first thin film layer 205 is formed between the touch panel 204 and the second substrate 206, and is located at the display region 220 and extends to the periphery region 210.

The first gap 231 is located in the periphery region 210 and exposes the display wire 207. The first gap 231 is formed through the second substrate 206 and the first thin film layer 205. For example, the first gap 231 may be formed by cutting a part of the second substrate 206 and the first thin film layer 205 in the periphery region 210. Such cutting may be completed using a cutter wheel or laser. Preferably, the first thin film layer 205 is a sealing layer.

Preferably, the display element 203 is an OLED element. The second thin film layer 205 is a low temperature polysilicon layer. According to the light emitting manner of the OLED element, the OLED element may have different structures. In an embodiment, the OLED element may be a cathode-emitting OLED element. The cathode-emitting OLED element includes an anode, an organic function layer and a cathode formed sequentially on the second thin film layer 205. The organic function layer includes a hole injection layer, a hole transport layer, a light emitting layer, an electron transport layer and an electron injection layer disposed sequentially on the anode. In another embodiment, the OLED element may an anode-emitting OLED element. The anode-emitting OLED element includes a cathode, an organic function layer and an anode formed sequentially on the second thin film layer 205. The organic function layer includes an electron injection layer, an electron transport layer, a light emitting layer, a hole transport layer and a hole injection layer disposed sequentially on the cathode.

FIG. 4 is a cross-sectional view of a display device taken along a B-B′ direction in FIG. 2 according to an embodiment of the present disclosure. A display region 220 of a display device 200 in FIG. 4 has the same structure as that in FIG. 3 except for a second gap 232 located in a periphery region 210 and exposing touch wires 208. The second gap 232 is formed through a first substrate 201 and a second thin film layer 202 in the periphery region 210. For example, the second gap 232 may be formed by cutting a part of the first substrate 201 and the second thin film layer 202 in the periphery region 210. Such cutting may be completed using a cutter wheel or laser.

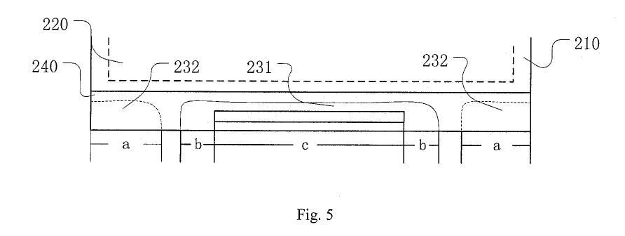

FIG. 5 is a diagram illustrating a bonding region of a display device according to an embodiment of the present disclosure.

Specific requirements of respective sizes of the second flexible circuit board and the first flexible circuit board in the bonding region 240 may be determined depending on specific products.

In a specific embodiment, a display panel is of 6.5 inches, a total width of the display panel is about 65 mm, the width c of the first flexible circuit board is 29 mm, and the bonding region (the first gap 231) of the first flexible circuit board plus the size of a chamfer and the size for avoidance of conflict when performing bonding is b (4 mm each side). The total width of bonding regions (two second gaps 232) of the second flexible circuit board for touch on both sides is 65-29-4-4=28 mm, and thus the width a of one second gap 232 is 14 mm, and this width is a total size for bonding of the second flexible circuit board at one side; with subtraction of 4 mm which includes the size of a chamfer and size for avoidance of conflict when performing bonding, the actual width of the bonding region at one side becomes 10 mm.

The two second gaps 232 are formed by cutting at both sides of the first gap 231, and the second flexible circuit board for touch has golden fingers at both sides, and thus an actual bonding size may be expanded to 20 mm, which is a design size that can accommodate a flexible circuit board for touch in the current market.

It is shall be noted that, in the above-described embodiments of the present disclosure, the first gap, the second gaps and the bonding regions for bonding the first flexible circuit board and the second flexible circuit board are located along a short side of the periphery region of the display device shown in FIG. 2, but the present disclosure is not limited to this, for example, they may be disposed along a long side of the periphery region.

As compared to the conventional technology, by appropriately arranging a bonding region for bonding the first flexible circuit board and the second flexible circuit board in a periphery region of a display device, the present disclosure has the following advantages:

1) circuit designs and wiring principles of the display panel and the flexible circuit boards of the present disclosure do not need to change, and the present disclosure is an improvement based on conventional processes;

2) without reduction of the bonding region of the in-cell first flexible circuit board, the present disclosure may increase the area of the bonding region(s) of the second flexible circuit board for touch by boding the second flexible circuit board for touch at both sides; and

3) the display device of the present disclosure has more advantages in an in-cell structure of a small-sized cellphone or tablet PC.

Exemplary embodiments of the present disclosure are shown and described above in detail. It should be understood that the present disclosure is not limited to the disclosed embodiments. On the contrary, the present disclosure is intended to cover various modifications and equivalent substitutions within the scope of the appended claims.

What is claimed is:

1. A display device having a display region and a periphery region, wherein the display device comprises:
a display panel which comprises:
a first substrate;
a display element located in the display region on the first substrate and having a display wire extending to the periphery region;
a touch panel located in the display region on the display element and having touch wires extending to the periphery region; and
a second substrate located on the touch panel and being opposite to the first substrate,
wherein the second substrate is provided with a first gap in the periphery region, and the first gap exposes the display wire, and
the first substrate is provided with two second gaps in the periphery region, and the two second gaps are respectively located at both sides of the first gap and expose the touch wires;
a first flexible circuit board for performing display and electrically connected to the display wire exposed by the first gap; and
a second flexible circuit board for touch and electrically connected to the touch wires exposed by the two second gaps.

2. The display device according to claim 1, wherein the first gap is located in a middle region of one side of the periphery region.

3. The display device according to claim 2, wherein the two second gaps are located at both sides of the first gap and extend to edges of the display panel.

4. The display device according to claim 1, wherein the first gap and the second gaps have any one shape selected from a group composed of a triangle, a rectangle, a trapezoid, a hexagon and an octagon.

5. The display device according to claim 1, wherein the first gap and the second gaps are located along a short side of the periphery region.

6. The display device according to claim 2, wherein the first gap and the second gaps are located along a short side of the periphery region.

7. The display device according to claim 3, wherein the first gap and the second gaps are located along a short side of the periphery region.

8. The display device according to claim 1, further comprising: a first thin film layer located between the touch panel and the second substrate,
wherein the first gap is formed through the second substrate and the first thin film layer.

9. The display device according to claim 8, wherein the first thin film layer is a sealing layer.

10. The display device according to claim 1, further comprising: a second thin film layer located between the first substrate and the touch panel,
wherein the second gaps are formed through the first substrate and the second thin film layer.

11. The display device according to claim 10, wherein the second thin film layer is a low temperature polysilicon layer.

12. The display device according to claim 1, wherein the second flexible circuit board has two golden fingers electrically connected to the touch wires exposed by the second gaps, respectively.

13. The display device according to claim 1, wherein the second flexible circuit board is approximately Y-shaped.

14. The display device according to claim 1, wherein the display element is an organic light emitting display element.

15. The display device according to claim 1, wherein the periphery region surrounds the display region.

16. The display device according to claim 2, wherein the second flexible circuit board has two golden fingers electrically connected to the touch wires exposed by the second gaps, respectively.

17. The display device according to claim 3, wherein the second flexible circuit board has two golden fingers electrically connected to the touch wires exposed by the second gaps, respectively.

18. The display device according to claim 2, wherein the second flexible circuit board is approximately Y-shaped.

19. The display device according to claim 3, wherein the second flexible circuit board is approximately Y-shaped.

20. The display device according to claim 2, wherein the periphery region surrounds the display region.
